(19) United States
(12) Patent Application Publication
(10) Pub. No.: US 2003/0048753 A1
(43) Pub. Date: Mar. 13, 2003

(54) Method and apparatus for multi-path elimination in a wireless communication system

(76) Inventor: Ahmad Jalali, San Diego, CA (US)

Correspondence Address: QUALCOMM Incorporated, Attn: Patent Department, 5775 Morehouse Drive, San Diego, CA, 92121-1714, US

(21) Appl. No.: 09/943,277

(22) Filed: Aug. 30, 2001

(51) Int. Cl. G01R 31/08; H04B 7/216

(52) U.S. Cl. 370/252; 370/335

(57) ABSTRACT

Method and apparatus for pre-coding in a communication system are disclosed. In a communication system, an origination station transmits a non pre-coded pilot signal and a pre-coded data signal. A destination station estimates a metric characterizing a communication channel using the non pre-coded pilot signal. The metric is then used to pre-code the data signal to be transmitted. The destination station may also use the estimated metric for demodulation of the pre-coded data. However, since the pilot signal is not pre-coded, the metric for the desired multi-path of the pilot channel differs from that of the pre-coded data channel, which may reduce the demodulation performance. To improve the channel estimation for data demodulation, the origination station may additionally transmit a dedicated pilot signal that is pre-coded in the same manner as the data signal destined to a specific user.

### BACKGROUND OF THE INVENTION

I. Field of the Invention

The current invention relates to communication. More particularly, the present invention relates to multi-path elimination in a wireless communication system.

II. Description of the Related Art

Communication systems have been developed to allow transmission of an information signal from an origination station to one or more physically distinct destination stations. In transmitting the information signal from the origination station over a communication channel, the information signal is first converted into a form suitable for efficient transmission over the communication channel. As used herein, the communication channel comprises a single path over which a signal is transmitted. Conversion, or modulation, of the information signal involves varying a parameter of a carrier wave in accordance with the information signal in such a way that the spectrum of the resulting modulated carrier is confined within the communication channel bandwidth. At the destination station the original information signal is replicated from the modulated carrier wave received over the communication channel. Such a replication is generally achieved by using an inverse of the modulation process employed by the origination station.

Modulation also facilitates multiple-access, i.e., simultaneous transmission and/or reception of several signals over a common communication channel. Multiple-access communication systems often include a plurality of remote subscriber units requiring intermittent service of relatively short duration rather than continuous access to the common communication channel. Several multiple-access techniques are known in the art, such as time division multiple-access (TDMA), frequency division multiple-access (FDMA), and amplitude modulation (AM). Another type of multiple-access technique is used in a code division multiple-access (CDMA) spread spectrum system that conforms to the “TIA/EIA/IS-95 Mobile Station-Base Station Compatibility Standard for Dual-Mode Wide-Band Spread Spectrum Cellular System,” hereinafter referred to as the IS-95 standard. The use of CDMA techniques in a multiple-access communication system is disclosed in U.S. Pat. No. 4,901,307, entitled “SPREAD SPECTRUM MULTIPLE-ACCESS COMMUNICATION SYSTEM USING SATELLITE OR TERRESTRIAL REPEATERS,” and U.S. Pat. No. 5,103,459, entitled “SYSTEM AND METHOD FOR GENERATING WAVEFORMS IN A CDMA CELLULAR TELEPHONE SYSTEM,” both assigned to the assignee of the present invention and incorporated herein by reference.

A multiple-access communication system may carry voice and/or data. An example of a communication system carrying both voice and data is a system in accordance with the IS-95 standard, which specifies transmitting voice and data over the communication channel. A method for transmitting data in code channel frames of fixed size is described in detail in U.S. Pat. No. 5,504,773, entitled “METHOD AND APPARATUS FOR THE FORMATTING OF DATA FOR TRANSMISSION”, assigned to the assignee of the present invention. In accordance with the IS-95 standard, the data or voice is partitioned into code channel frames that are 20 milliseconds wide with data rates as high as 14.4 kbps. Additional examples of communication systems carrying both voice and data are communication systems conforming to the “3rd Generation Partnership Project” (3GPP), embodied in a set of documents including Document Nos. 3G TS 25.211, 3G TS 25.212, 3G TS 25.213, and 3G TS 25.214 (the W-CDMA standard), or “TR-45.5 Physical Layer Standard for cdma2000 Spread Spectrum Systems” (the IS-2000 standard).

An example of a data only communication system is a high data rate (HDR) communication system, such as the communication system disclosed in co-pending application Ser. No. 08/963,386, entitled “METHOD AND APPARATUS FOR HIGH RATE PACKET DATA TRANSMISSION,” filed Nov. 3, 1997, assigned to the assignee of the present invention. The HDR communication system defines a set of data rates, ranging from 38.4 kbps to 2.4 Mbps, at which an origination station (access point, AP) may send data to a receiving terminal (access terminal, AT).

The information signal to be exchanged among the terminals in a communication system is often organized into a plurality of packets. For the purposes of this description, a packet is a group of bytes, including data (payload) and control elements, arranged into a specific format. The control elements comprise, e.g., a preamble and a quality metric. The quality metric comprises, e.g., cyclical redundancy check (CRC), parity bit(s), and other types of metric known to one skilled in the art. The packets are usually formatted into a message in accordance with a communication channel structure. The message, appropriately modulated, traveling between the origination station and the destination station, is affected by characteristics of the communication channel, e.g., signal-to-noise ratio, fading, time variance, and other such characteristics. Such characteristics affect the modulated signal differently in different communication channels. Consequently, transmission of a modulated signal over a wireless communication channel requires different considerations than transmission of a modulated signal over a wire-like communication channel, e.g., a coaxial cable or an optical cable. In addition to selecting modulation appropriate for a particular communication channel, other methods for protecting the information signal have been devised. Such methods comprise, e.g., encoding, symbol repetition, interleaving, and other methods known to one of ordinary skill in the art. However, these methods increase overhead. Therefore, an engineering compromise between reliability of message delivery and the amount of overhead must be made. Even with the above-discussed protection of information, the conditions of the communication channel can degrade to the point at which the destination station possibly cannot decode (erases) some of the packets comprising the message. In data-only communications systems, the cure is to re-transmit the non-decoded packets using an Automatic Retransmission reQuest (ARQ) made by the destination station to the origination station.

One characteristic, affecting the communication link in wireless communication systems is an intra-cell multi-path interference. The intra-cell multi-path interference is caused by an existence of multiple paths along which a signal, transmitted from an origination station, reaches a destination station. The concept of a multi-path interference is illustrated in FIG. 1, where the origination station, e.g., a base station (BS) 102 transmits a signal, which reaches the destination station, e.g., a remote station (RS) 104 along two paths 106, 108. The presence of multi-path reduces received carrier to interference (C/I) ratio. The received C/I can be determined in accordance with the following equation:

$$\frac{C}{I} = \frac{{S}_{1}}{I + {S}_{2}} + \frac{{S}_{2}}{I + {S}_{1}} , \qquad ( 1 )$$

where:

C is the signal carrier power received,

I is the interference,

S₁ is the component of signal power received along path 106, and

S₂ is the component of signal power received along path 108.

Elimination of the multi-path components, e.g., path 108, reduces Equation (1) to the following equation:

$$\frac{C}{I} = \frac{S}{I} , \qquad ( 2 )$$

where:

S==S₁+S₂

is the signal power received.

One of ordinary skill in the art recognizes that the C/I ratio given by Equation (2) is greater than the C/I ratio given by Equation (1). Therefore, reduction of the intra-cell interference caused by multi-path components results in an increase of the received C/I. Increased C/I at the RS 104 benefits performance of a wireless communication system by, e.g., increase in capacity, increase in data throughput, and providing other benefits known to one skilled in the art. Therefore, it is desirable to eliminate the multi-path interference. One approach to eliminate the multi-path interference utilizes equalization and pre-coding techniques.

FIG. 2 illustrates a method eliminating the multi-path components by equalization at a receiver. A transmitter 202 transmits signal S_{Transmitted} over a communication link 204. The communication link is characterized by a metric, e.g., an impulse response, a transfer function or other characteristics known to one skilled in the art. For the purposes of illustration, a transfer function A(z) is used. The communication link introduces noise N 206 and the resulting signal and noise is provided to an equalizer 208. If the equalizer is characterized by a transfer function

$$\frac{1}{A ( z )} ,$$

then a receiver 210 receives signal given by the following equation:

$${S}_{Received} = ( {S}_{Transmitted} \cdot A ( z ) + N ) \cdot \frac{1}{A ( z )} = {S}_{Transmitted} + \frac{N}{A ( z )} , \qquad ( 3 )$$

where:

N is the communication channel noise,

S_{Transmitted} is the signal transmitted, and

S_{Received} is the signal received.

A disadvantage of this approach is potential amplification of noise for A(z)<<1. Pre-coding the signal at a transmitter instead of performing equalization at the receiver may eliminate this disadvantage. Pre-coding at the transmitter is illustrated in FIG. 3. A transmitter 302 comprises a data source 304, which provides data to be transmitted to a pre-coder 306. The pre-coded data are then transmitted over a communication channel 308, characterized by a transfer function A(z). The communication channel introduces noise N 310 and the resulting signal and noise are provided to a receiver 312. If the pre-coder 306 is characterized by a transfer function 1/A(z), then the receiver 312 receives a signal given by the following equation:

$${S}_{Received} = {S}_{Transmitted} \cdot \frac{1}{A ( z )} \cdot A ( z ) + N = {S}_{Transmitted} + N \qquad ( 4 )$$

Examination of Equation 4 reveals that the noise amplification problem has been eliminated for all values of A(z), however, for A(z)<<1 the power required for correct pre-coding may exceed the transmitter's 302 available power. To eliminate the available power problem, one pre-coding scheme performs a (1/A(z))mod(P_{Transmitted}) transformation on the data prior to transmission. P_{Transmitted} is the maximum power level at which the transmitter can transmit. At the receiver an inverse transformation mod(P_{Transmitted}) is carried out on the received data prior to decoding.

Further details of pre-coding may be found in M. Tomlinson, “New automatic equalizer employing modulo arithmetic,” Electronic Letters, Vol. 7, March 1971, pp 138-139, and G. D. Forney and M. V. Eyuboglu, “Combined equalization and coding using pre-coding,” IEEE Comm. Magazine, December 1991, pp. 25-34.

Based on the foregoing, there exists a need in the art for a method and an apparatus eliminating multi-path by applying pre-coding and equalization to multiple-access wireless communication system.

### SUMMARY OF THE INVENTION

In one aspect of the invention, the above-stated needs are addressed by determining a pre-coder parameters; pre-coding first data in accordance with said determined pre-coder parameters; transmitting a pre-coded first data; and transmitting a non pre-coded first reference data. The pre-coder parameters are determined by receiving a reference data; and determining the pre-coder parameters in accordance with said received reference data and the reference data.

In another aspect of the invention, the pre-coder parameters are determined by receiving the non pre-coded first reference data; determining the pre-coder parameters in accordance with said received non pre-coded first reference data and the first reference data; and transmitting said determined pre-coder parameters.

In another aspect of the invention, the pre-coder parameters are determined by equalizing the received non pre-coded first reference data and provide equalized non pre-coded first reference data; determining the pre-coder parameters by adjusting characteristics of the at least two equalizers in accordance with the received non pre-coded first reference data and the first reference data; and transmitting said determined pre-coder parameters.

In yet another aspect of the invention, the above-stated needs are addressed by receiving a reference data and a pre-coded data; and determining demodulator parameters in accordance with the said received reference data and the reference data; and demodulating the pre-coded data in accordance with said determined demodulator parameters.

### BRIEF DESCRIPTION OF THE DRAWINGS

The features, objects, and advantages of the present invention will become more apparent from the detailed description set forth below when taken in conjunction with the drawings in which like reference characters identify elements correspondingly throughout and wherein:

FIG. 1 is a conceptual illustration of multi-path interference;

FIG. 2 is a conceptual illustration of equalization of multi-path interference at a receiver;

FIG. 3 is a conceptual illustration of pre-coding at a transmitter and equalization of multi-path interference at a receiver;

FIG. 4 illustrates a conceptual diagram of a multiple-access communication system.

FIG. 5 illustrates a forward link waveform in accordance with one embodiment of the invention;

FIG. 6 illustrates a forward link channel time-slot in accordance with another embodiment of the invention;

FIG. 7 is a block diagram of a transmit terminal in accordance with one embodiment of the invention; and

FIG. 8 is a block diagram of a receive terminal in accordance with one embodiment of the invention.

FIG. 9 illustrates a conceptual diagram of a multiple-access communication system with multiple receive antennae.

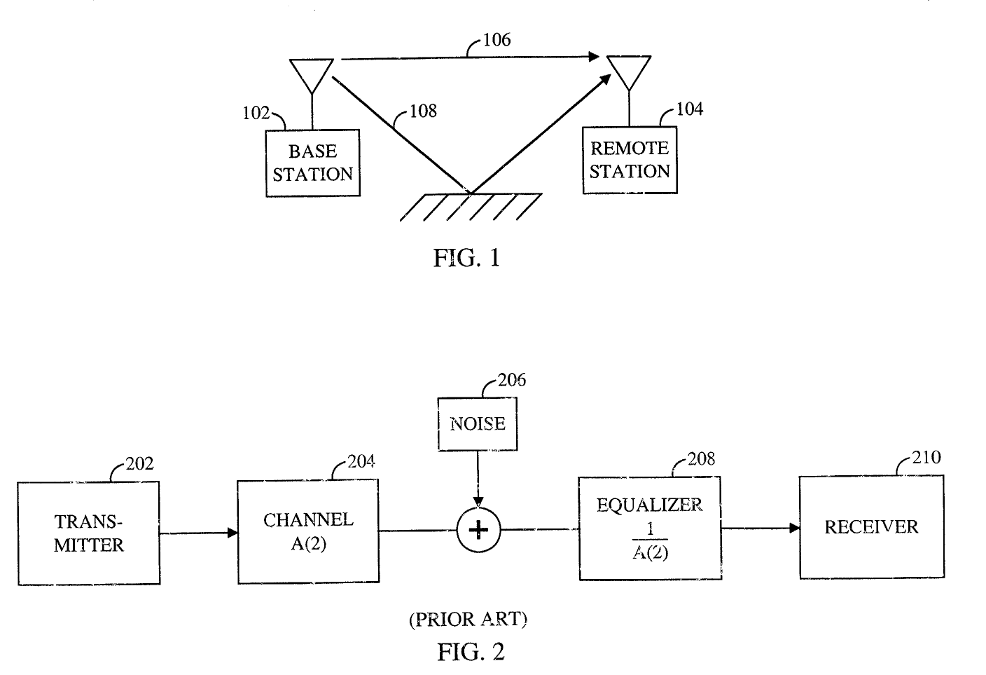

### DETAILED DESCRIPTION OF PREFERRED EMBODIMENTS

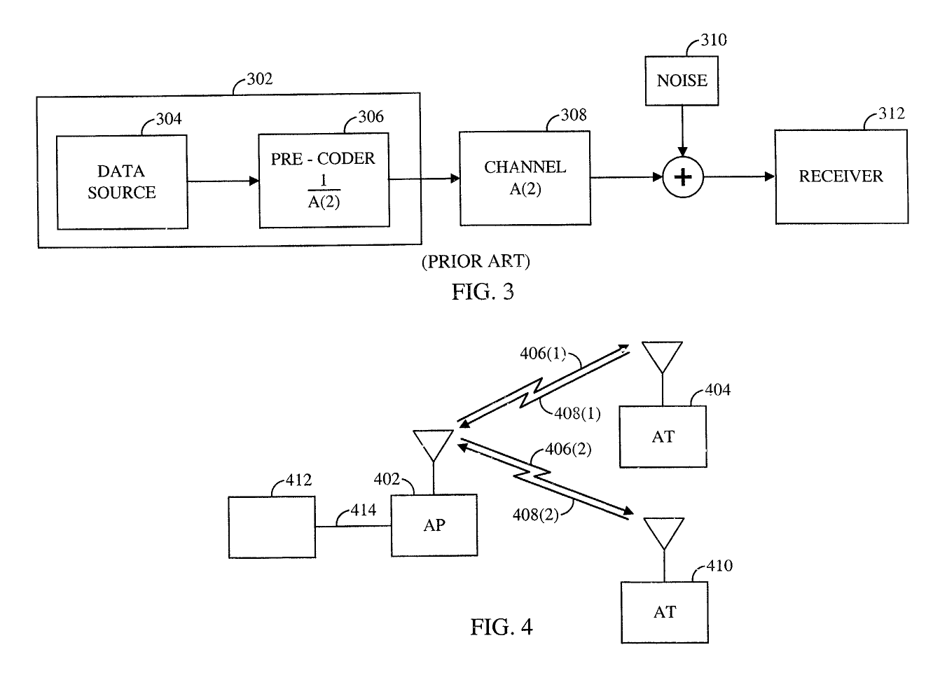

FIG. 4 illustrates a conceptual diagram of a multiple-access communication system 400 capable of performing the method in accordance with embodiments of the present invention. An AP 402 transmits data to an AT 404 over a forward link 406(1), and receives data from the AT 404 over a reverse link 408(1). Similarly, the AP 402 transmits data to the AT 410 over a forward link 406(2), and receives data from the AT 410 over a reverse link 408(2). In accordance with the exemplary embodiment of the data communication system of the present invention, forward link data transmission occurs from one AP to one AT. Reverse link data communication occurs from one AT to one or more APs. Although only two ATs and one AP is shown in FIG. 4, one of ordinary skills in the art recognizes that this is for pedagogical purposes only, and the multiple-access communication system may comprise plurality of ATs and APs.

In one embodiment, each AP in the communication system 400 transmits known signal, called a pilot signal. In one embodiment, the pilot signal is transmitted at well-defined, periodic intervals on the forward traffic channel. In another embodiment, the pilot signal is transmitted continuously on a separate forward channel. For the purposes of this description, channel is a route for transmitting signals distinct from other parallel routes; thus, channel routes may be separated by e.g., a frequency division, a time division, a code division, and others known to one skilled in the art.

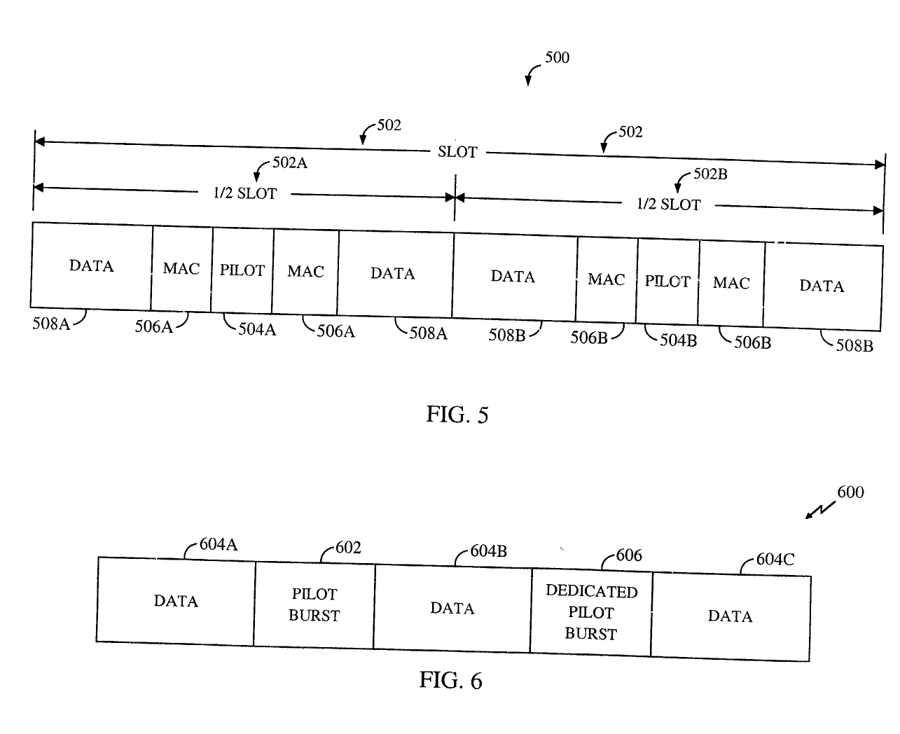

FIG. 5 illustrates an exemplary forward link waveform 500. For pedagogical reasons, the waveform 500 is modeled after a forward link waveform of the above-mentioned HDR system. However, one of ordinary skill in the art will understand that the teaching is applicable to different waveforms. Thus, for example, in one embodiment, the waveform does not need to contain pilot signal bursts, and the pilot signal can be transmitted on a separate channel, which can be continuous or bursty. The forward link 500 is defined in terms of frames. A frame is a structure comprising 16 time-slots 502, each time-slot 502 being 2048 chips long, corresponding to a 1.66. ms. time-slot duration, and, consequently, a 26.66. ms. frame duration. For the purposes of this description, a time-slot is a fixed time interval comprising a variable number of bits, depending on a data rate. Each time-slot 502 is divided into two half-time-slots 502a, 502b, with pilot bursts 504a, 504b transmitted within each half-time-slot 502a, 502b. In the exemplary embodiment, each pilot burst 504a, 504b is 96 chips long, and is centered at the mid-point of its associated half-time-slot 502a, 502b. The pilot bursts 504a, 504b comprise a pilot channel signal covered by a Walsh cover with index 0. A forward medium access control channel (MAC) 506 forms two bursts, which are transmitted immediately before and immediately after the pilot burst 504 of each half-time-slot 502. In the exemplary embodiment, the MAC is composed of up to 64 code channels, which are orthogonally covered by 64-ary Walsh codes. Each code channel is identified by a MAC index, which has a value between 1 and 64, and identifies a unique 64-ary Walsh cover. A reverse power control channel (RPC) is used to regulate the power of the reverse link signals for each subscriber station. The RPC is assigned to one of the available MACs with MAC index between 5 and 63. The MAC with MAC index 4 is used for a reverse activity channel (RA), which performs flow control on the reverse traffic channel. The forward link traffic channel and control channel payload is sent in the remaining portions 508a of the first half-time-slot 502a and the remaining portions 508b of the second half-time-slot 502b.

The pilot burst 504 provides the ATs with means for predicting a quality metric of the received signal. Referring back to FIG. 4, initially, the AP 402 and one of the ATs, e.g., AT 404, establish a communication link using a predetermined access procedure. In this connected state, the AT 404 is able to receive data and control messages from the AP 402, and is able to transmit data and control messages to the AP 402. The AT 404 then monitors the forward link for transmissions from all the APs in an active set of the AT 404. The active set comprises list of all the APs capable of communication with the AT 404. The AT 404 then determines for each AP in the AT 404 active set a quality metric for the forward link, which in one embodiment comprises a signal-to-noise-and-interference ratio (SINR). In one embodiment, the AT 404 monitors the pilot bursts 504 (of FIG. 5) received from all the APs belonging to the AT 404 active set, and utilizes the pilot bursts 502 to determine the SINR of the forward link signals. If the quality metric from a particular AP, e.g., AP 402, is above a predetermined add threshold or below a predetermined drop threshold, the AT 404 reports this to the AP 402. Subsequent messages from the AP 402 direct the AT 404 to add to or delete from its active set the particular AP. Based on the SINR information over past signal segment(s) from each of the APs in the AT 404 active set, the AT 404 predicts the SINR over future signal segment(s) for each of the APs in the AT 404 active set. In one embodiment, the signal segment is a time slot. An exemplary prediction method is disclosed in co-pending application Ser. No. 09/394,980 entitled “SYSTEM AND METHOD FOR ACCURATELY PREDICTING SIGNAL TO INTERFERENCE AND NOISE RATIO TO IMPROVE COMMUNICATIONS SYSTEM PERFORMANCE,” assigned to the assignee of the present invention. Because different destination stations utilize the pilot burst 504, an AP 402 must not implement pre-coding on the pilot burst 504.

The AT 404 continues to measure the SINR of the forward link signals from the APs, and selects the serving AP from the active set based on a set of parameters. The set of parameters can comprise the present and previous SINR measurements and the bit-error-rate or packet-error-rate. In one embodiment, the serving AP is selected based on the largest SINR measurement. The AT 404 then identifies the serving AP and transmits to the selected AP a data request message (hereinafter referred to as the DRC message) on the data request channel (hereinafter referred to as the DRC channel). The DRC message can contain the requested data rate or, alternatively, an indication of the quality of the forward link channel (e.g., the SINR measurement itself, the bit-error-rate, or the packet-error-rate). In one embodiment, the AT 404 can direct the transmission of the DRC message to a specific AP by the use of a Walsh code which uniquely identifies the base station. The DRC message symbols are exclusively OR'ed (XOR) with the unique Walsh code. Since each AP in the active set of the AT 404 is identified by a unique Walsh code, only the selected AP which performs the identical XOR operation as that performed by the AT 404, with the correct Walsh code, can correctly decode the DRC message.

In an embodiment, the communication system 400 utilizes a time division duplex (TDD). A TDD means that both the forward link and the reverse link are transmitted on the same carrier frequency. Due to the frequency reciprocity, the characteristic of the forward link and the reverse link are equal. Therefore, the AP may use the reverse link impulse response estimate to carry out pre-equalization on the forward link. In one embodiment, the AP 402 estimates the reverse link impulse response from the signals sent by the AT 404 on the reverse link.

In another embodiment, the communication system 400 utilizes a frequency division duplex (FDD). A FDD means that the forward link is carried on one carrier frequency, and the reverse link is carried on a different carrier frequency. Because of the carrier frequency difference, the characteristic of the forward link and the reverse link will generally be different. Therefore, to characterize the forward link in FDD systems, the AT 404 uses the pilot burst 502 to estimate the forward link characteristics A(z). The forward link characteristics comprises an impulse response, a transfer function or other characteristics known to one skilled in the art. The AT 404 then transmits the channel impulse response that it determined to the AP on a reverse link channel.

When data to be transmitted to the AT 404 arrive to the controller 412, in one embodiment, the controller 412 sends the data to all APs in AT 404 active set over the backhaul 414. The term backhaul is used to mean a communication link between a controller and an AP. In another embodiment, the controller 412 first determines which AP was selected by the AT 404 as the serving AP, e.g., AP 402, and then sends the data to the determined AP. The data are stored in a queue at the AP(s). A paging message is then sent by one or more APs to the AT 404 on the respective control channels. The AT 404 demodulates and decodes the signals on one or more control channels to receive the paging messages.

At each time slot, the AP 402 can select any of the paged AT for data transmission. The AP 402 uses the rate control information received from each AT in the DRC message to efficiently transmit forward link data at the highest possible rate. In one embodiment, the AP 402 determines the data rate at which to transmit the data to the AT 404 based on the most recent value of the DRC message received from the AT 404. Additionally, the AP 402 uses the channel characteristic A(z) received over the reverse channel to pre-code the data portion of the forward link with the above-discussed principles.

The AT 404, for which the data is intended, receives the data transmission and decodes the data. In one embodiment the AT 404 may use the pilot burst 504 to estimate the complex channel gain of the communication channel and utilize this estimate for demodulation of data. As explained, the pilot signal is used to estimate the forward link characteristic A(z), yielding an estimate Â(z). A data symbol t is then pre-coded by

$$\frac{1}{\hat{A} ( z )} ,$$

and sent over a forward link. The AT 404 receives a signal symbol r corresponding to the transmitted symbol t given by the following Equation:

$$r = t \cdot \frac{1}{\hat{A} ( z )} \cdot A ( z ) + n \approx t \cdot a \cdot {ⅇ}^{- jθ} + n \qquad ( 5 )$$

where:

a is an amplitude introduced by difference between Â(z) and A(z);

e is a base of natural system of logarithms;

θ is a phase introduced by difference between Â(z) and A(z); and

n is a noise added by the forward link.

To remove the amplitude and the phase distortion, an estimate of the link complex gain is required. It follows from Equation (5) that if the signal symbol r is known at the AT 404, the AT 404 can calculate the amplitude a and the phase θ. Although the pilot burst 402 is a known signal, because the pilot burst 402 was not pre-coded, the quality metric on the desired multi-path of the common pilot channel is, due to the presence of an unequalized pilot channel multi-path, smaller than the quality metric of the data channel with equalized multi-paths. Consequently, the link characteristic estimated from the received pilot signal is different from the data link with equalized multi-paths. Therefore, Equation (5) is not satisfied, and the noisy channel characteristic estimate may reduce performance of a receiver (not shown) at the AT 404. In order to improve the link estimation for data demodulation, in accordance with one embodiment, an additional pilot signal, referred to as a dedicated pilot signal is introduced on the forward link. The dedicated pilot signal is pre-coded in the same manner as the data destined to a specific destination station. Consequently, the dedicated pilot signal is equalized, and the specific destination station uses the dedicated pilot signal for demodulation. In one embodiment, the dedicated pilot signal is transmitted at well-defined, periodic intervals on the forward traffic channel. In another embodiment, the dedicated pilot signal is transmitted continuously on a separate forward channel.

FIG. 6 is a simplified illustration of a forward link channel time-slot 600 in accordance with one embodiment of the invention. The time-slot 600 contains a pilot burst 602, data 604a, 604b, 604c, and dedicated pilot burst 606. Because the forward link is comprised of frames, wherein each frame comprises a concatenation of number of time-slots, the pilot burst 602 and the dedicated pilot burst 606 repeat themselves periodically. One of ordinary skills in the art understands that all other channels necessary supporting other functions of the communication system as described in reference to FIG. 5 are present in the forward link channel time-slot 600, e.g., MAC, RBC, and other channels. In accordance with this embodiment, the pilot burst 602 provides the destination stations with a means of predicting a quality metric of the received signal. In one embodiment, the quality metric is a carrier-to-interference ratio (C/I). Because different destination stations utilize the pilot burst 602, an origination station must not implement pre-coding on the pilot burst 602. The dedicated pilot burst 606 is pre-coded in the same manner as the data destined to a specific AT. The specific AT uses the dedicated pilot burst 606 for demodulation in accordance with the above-described principles.

However, one of ordinary skill in the art will understand that the teaching is applicable to different waveforms. Thus, for example, in one embodiment, the pilot burst and the dedicated pilot burst can be sent in each half time slot. Consequently, a time slot in accordance with this embodiment would comprise two half time-slots, each time-slot having the structure as illustrated in FIG. 6. In another embodiment, the waveform contains the dedicated pilot signal bursts, and the pilot signal can be transmitted on separate channel, which can be continuous or bursty.

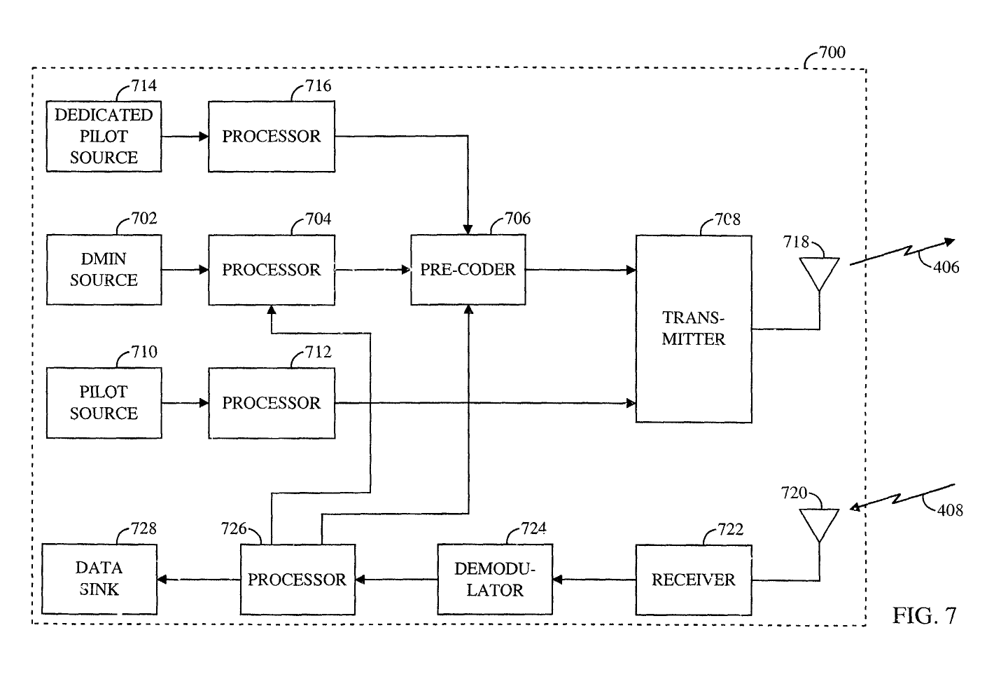

FIG. 7 is a block diagram of an AP 700, in accordance with one embodiment of the invention. Data to be transmitted are provided by a variable data source 702 to a processor 704. The processor 704 processes the data in accordance with CDMA principles and provides the data to a pre-coder 706. The pre-coder 706 pre-codes the data and provides the data to a transmitter 708. The transmitter 708 is further provided with a pilot signal generated by a pilot source 710 and processed in accordance with CDMA principles by a processor 712. In accordance with one embodiment of the invention, the transmitter 708 multiplexes the pre-coded data and the pilot signal to provide channel time-slots in accordance with principles described with reference to FIG. 5.

In accordance with another embodiment of the invention, the origination station 700 further comprises dedicated pilot source 714. The pilot data provided by the dedicated pilot source 714 is processed in accordance with CDMA principles by processor 716, and provided to the pre-coder 706. The pre-coder 706 pre-codes the pilot data and provides the processed pilot data to the transmitter 708. The transmitter 708 multiplexes the pre-coded data, the pilot signal, and the dedicated pilot signal to provide channel time-slots in accordance with principles described with reference to FIG. 6.

The channel time-slots are then quadrature spread, baseband filtered, upconverted and transmitted from antenna 718 on a forward link 406.

Signals on a reverse link 408 are received by an antenna 720 and provided to a receiver 722, which downconverts, filters and despreads the signal. The despread signal is provided to a demodulator 724 and further to a processor 726. The processor 726 extracts a data rate control signal and provides it to the processor 704.

If a FDD communication system is utilized, the channel impulse response seen by the AT and the AP are generally different. Therefore, in FDD systems the AT must transmit the channel impulse response that it determined to the AP on a reverse link feedback channel. Therefore, the processor 726 further extracts the impulse response information and provides the estimate to the pre-coder 706.

In a TDD communication system, where both the AT and the AP transmit on same frequency, the AP, due to the reciprocity of the forward and reverse link channels, may use its own channel impulse response estimate to carry out pre-equalization on the forward link. In this embodiment, the processor 726 estimates the channel impulse response from the signals sent on the reverse link and provides the estimate to the pre-coder 706. The data is provided to data sink 728.

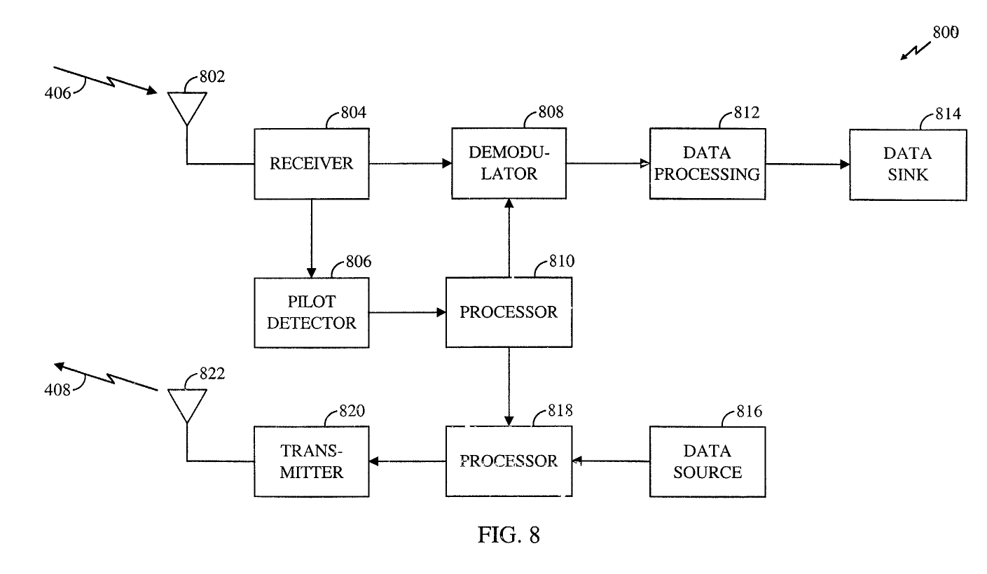

FIG. 8 is a block diagram of an AT 800 in accordance with one embodiment of the invention. The signal on the forward link 406 are captured by an antenna 802 and provided to a receiver 804, which downconverts, filters, and despreads the signal. The signal is provided to a pilot detector 806 and a demodulator 808. The pilot detector 806 detects and extracts a pilot signal, which is then provided to a processor 810.

In accordance with one embodiment of the invention, the processor 810 uses the pilot burst to estimate the complex channel gain of the channel that the AT 800 believes has been pre-coded by the AP, and provides this estimate to the demodulator 808. The demodulator 808 utilizes this estimate for demodulation of the data.

In accordance with another embodiment of the invention, the processor 810 uses the dedicated pilot burst to estimate the complex channel gain of the channel that has been pre-coded by the AP and provides this estimate to the demodulator 808. The demodulator 808 utilizes this estimate for demodulation of the data.

The processor 810 further uses the pilot burst to estimate the SINR, and uses this value to predict the SINR of the pre-coded signal over at least one next time-slot. The predicted SINR value is then used to generate a DRC, which is provided to a processor 818. The processor 818 provides the DRC together with the complex channel gain and traffic data to be transmitted, which are generated by data source 816, to transmitter 820. The data are then quadrature spread, baseband filtered, upconverted and transmitted from antenna 822 on reverse link 408.

### Extension to Multiple Receiving Antennae

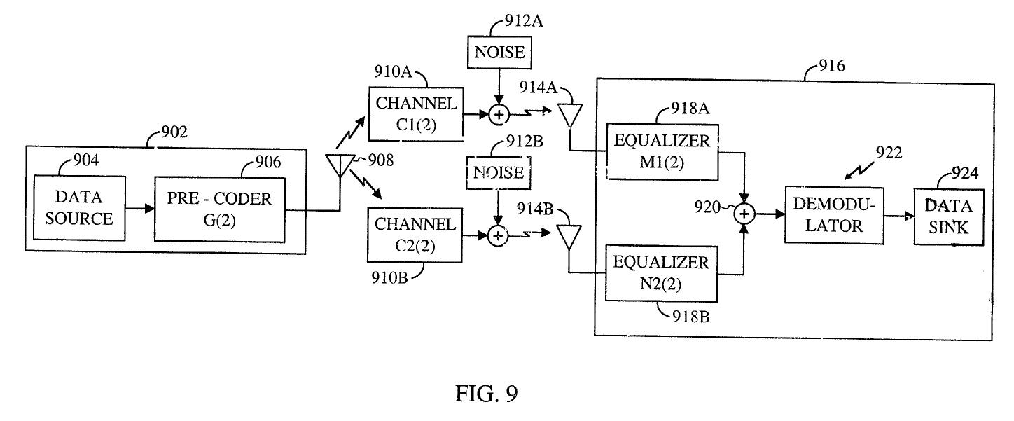

FIG. 9 illustrates extension of the above-described concept to an often-used configuration of a communication system, where an AP 902 transmit a signal from one antenna 908, and an AT 916 receives the signal at multiple antennae. For the purposes of explanation, only two antennae 914a and 914b are illustrated. One of ordinary skills in the art will understand how to extend the described embodiments to multiple antennae.

The AP 902 comprises a data source 904, which provides data to a pre-coder 906 that pre-codes the data in accordance with a function G(z) in accordance with the above-described embodiments. One of ordinary skills in the art understands that although not shown in FIG. 9, the AP 902 further comprises all the illustrative logical blocks, modules, and circuits as illustrated in reference to FIG. 7 and accompanying text, necessary to generate a forward link waveform in accordance with the above-described embodiments. The forward link waveform is then transmitted via an antenna 908.

The forward link waveform arrive at an antenna 914a of the AT 916 over a communication channel 910a, characterized by a transfer function C₁(z). The communication channel 910a introduces noise 912a, and the resulting signal and noise are provided to an equalizer 918a, characterized by a transfer function H₁(z). The data also arrive at an antenna 914b of the AT 916 over a communication channel 910b, characterized by a transfer function C₂(z). The communication channel 910b introduces noise 912b, and the resulting signal and noise are provided to an equalizer 918b, characterized by a transfer function H₂(z). Consequently, the demodulator 922 at the output of the summer 920 receives a signal modified by the transfer function R(z), given by the following equation:

R(z)=G(z)·C₁(z)H(z)+G(z)−C₂(z)·H₂(z) (5)

The AT 916 estimates the transfer functions C₁(z), C₂(z), in accordance with the above-described embodiments and adjusts H₁(z), H₂(z), and G(z) to optimize a signal quality metric, e.g., maximum SINR at the demodulator 922. The data decoded in accordance with the above-described embodiments are provided to a data sink 924. The destination station 916 then computes and reports G(z) back to the origination station 902.

One of ordinary skills in the art understands that although not shown in FIG. 9, the AT 916 further comprises all the illustrative logical blocks, modules, and circuits as illustrated in reference to FIG. 8 and accompanying text, necessary to carry out the processing (e.g., forward link reception, pilot signal extraction, channel estimation) in accordance with the above-described embodiments.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal (presumably previously defined broadly). In the alternative, the processor and the storage medium may reside as discrete components in a user terminal.

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

What is claimed is:

1. A method for pre-coding in a communication system, comprising:
determining pre-coder parameters;
pre-coding first data in accordance with said determined pre-coder parameters;
transmitting said pre-coded first data; and
transmitting non pre-coded first reference data.

2. The method as claimed in claim 1 wherein determining a pre-coder parameters comprises:
receiving a reference data; and
determining the pre-coder parameters in accordance with said received reference data and the reference data.

3. The method as claimed in claim 1 wherein determining a pre-coder parameters comprises:
receiving the non pre-coded first reference data;
determining the pre-coder parameters in accordance with said received non pre-coded first reference data and the first reference data; and
transmitting said determined pre-coder parameters.

4. The method as claimed in claim 3 further comprising:
receiving said determined pre-coder parameters; and
providing said determined pre-coder parameters to the pre-coder.

5. The method as claimed in claim 1 wherein pre-coding first data in accordance with said determined parameters comprises:
pre-coding a payload data; and
pre-coding a dedicated pilot data.

6. The method of claim 1 wherein said transmitting a non pre-coded reference data comprises:
transmitting a continuous non pre-coded reference data.

7. The method of claim 1 wherein said transmitting a non pre-coded reference data comprises:
transmitting a discontinuous non pre-coded reference data.

8. The method of claim 1 wherein said transmitting a non pre-coded reference data comprises:
transmitting a pilot data.

9. The method as claimed in claim 1, further comprising:
receiving the non pre-coded first reference data at least two antennae;
equalizing each of said received non pre-coded first reference data by an equalizer and provide equalized non pre-coded first reference data;
determining the pre-coder parameters by adjusting characteristics of the at least two equalizers in accordance with the received non pre-coded first reference data and the first reference data; and
transmitting said determined pre-coder parameters.

10. The method as claimed in claim 9 wherein said determining the pre-coder parameters by adjusting characteristics of the at least two equalizers in accordance with the received non pre-coded first reference data and the first reference data comprises:
optimizing a quality metric of a composite data comprising the equalized non pre-coded first reference data.

11. A method for demodulating pre-coded data, comprising:
receiving a reference data and a pre-coded data; and
determining demodulator parameters in accordance with the said received reference data and the reference data; and
demodulating the pre-coded data in accordance with said determined demodulator parameters.

12. The method as claimed in claim 11 wherein the reference data comprise a non pre-coded pilot signal.

13. The method as claimed in claim 11 wherein the reference data comprise a pre-coded pilot signal.

14. The method as claimed in claim 11 wherein the reference data are continuous reference data.

15. The method as claimed in claim 11 wherein the reference data are discontinuous reference data.

16. An apparatus for pre-coding in a communication system, comprising:
a pre-coder configured to pre-code data in accordance with pre-coder parameters; and
a first transmitter communicatively coupled to said pre-coder configured to:
transmit the pre-coded data; and
transmit a non pre-coded first reference data.

17. The apparatus as claimed in claim 16, further comprising:
a first receiver communicatively coupled to said pre-coder configured to receive a reference data;
a first processor communicatively coupled to said first receiver; and
a storage medium communicatively coupled to said first processor and containing a set of instructions executable by the processor to:
determine the pre-coder parameters in accordance with said received reference data and the reference data.

18. The apparatus as claimed in claim 16, further comprising:
a second receiver configured to receive the non pre-coded first reference data;
a second processor communicatively coupled to said second receiver;
a storage medium communicatively coupled to said first processor and containing a set of instructions executable by the processor to:
determine the pre-coder parameters in accordance with said received non pre-coded first reference data and the non pre-coded first reference data; and
a second transmitter communicatively coupled to said second processor configured to transmitting said determined pre-coder parameters.

19. The apparatus as claimed in claim 18, wherein said first receiver is further configured to:
receive said determined pre-coder parameters; and
provide said received pre-coder parameters to said pre-coder.

20. The apparatus as claimed in claim 16 wherein said pre-coder is further configured to pre-code a second reference data in accordance with the determined parameters; and
wherein said first transmitter is further configured to transmit the pre-coded second reference data.

21. The apparatus as claimed in claim 16 wherein said first transmitter is further configured to transmit the non pre-coded first reference data continuously.

22. The apparatus as claimed in claim 16 wherein said first transmitter is further configured to transmit the non pre-coded first reference data discontinuously.

23. The apparatus of claim 16 wherein said non pre-coded first reference data comprise a pilot data.

24. The apparatus as claimed in claim 20 wherein said first transmitter is further configured to transmit the pre-coded second reference data continuously.

25. The apparatus as claimed in claim 20 wherein said first transmitter is further configured to transmit the pre-coded second reference data discontinuously.

26. The apparatus of claim 20 wherein said pre-coded second reference data comprise a dedicated pilot data.

27. The apparatus as claimed in claim 16, further comprising:
at least two equalizers configured to accept the received non pre-coded first reference data and provide equalized non pre-coded first reference data;
a processor communicatively coupled to said at least two equalizers;
a storage medium communicatively coupled to the processor and containing a set of instructions executable by the processor to determine said pre-coder parameters by adjusting characteristics of the at least two equalizers in accordance with the received non pre-coded first reference data and the first reference data; and
a second transmitter communicatively coupled to said processor configured to transmit the determined pre-coder parameters.

28. The apparatus as claimed in claim 16 wherein said processor determines said pre-coder characteristics by adjusting characteristics of the at least two equalizers in accordance with the non pre-coded first reference data the first reference data by executing a set of instructions to:
optimize a quality metric of a composite data comprising the equalized non pre-coded first reference data.

29. An apparatus for demodulating pre-coded data, comprising:
a first receiver configured to:
receive a reference data and a pre-coded data; and
determine demodulator parameters in accordance with the said received reference data and the reference data; and
a demodulator communicatively coupled to said receiver configured to demodulate the pre-coded data in accordance with said determined demodulator parameters.

30. The apparatus as claimed in claim 29 wherein the reference data comprise a non pre-coded pilot signal.

31. The apparatus as claimed in claim 29 wherein the reference data comprise a pre-coded pilot signal.

32. The apparatus as claimed in claim 29 wherein the reference data are continuous reference data.

33. The apparatus as claimed in claim 29 wherein the reference data are discontinuous reference data.

34. A digital signal processing apparatus for pre-coding in a communication system, comprising:
memory storage unit; and
a digital signal processor communicatively coupled to said memory storage unit, and capable of executing instructions to:
determine pre-coder parameters;
pre-code first data in accordance with the determined pre-coder parameters; and
assist in preparing the pre-coded first data and non pre-coded first reference data for transmission.

35. A digital signal processing apparatus for demodulating pre-coded data in a communication system, comprising:
memory storage unit; and
a digital signal processor communicatively coupled to said memory storage unit, and capable of executing instructions to:
accept a reference data and a pre-coded data;
determine demodulating parameters in accordance with the accepted reference data and the reference data; and
demodulate the pre-coded data in accordance with the determined demodulating parameters.

36. An apparatus for pre-coding in a communication system, comprising:
means for determining a pre-coder parameters;
means for pre-coding first data in accordance with said determined pre-coder parameters;
means for transmitting said pre-coded first data and a non pre-coded first reference data.

37. An apparatus for demodulating pre-coded data, comprising:
means for receiving a reference data and a pre-coded data; and
means for determining demodulator parameters in accordance with the said received reference data and the reference data; and
means for demodulating the pre-coded data in accordance with said determined demodulator parameters.
